(19) United States
(12) Patent Application Publication
(10) Pub. No.: US 2021/0204068 A1
(43) Pub. Date: Jul. 1, 2021

(54) MEMS Microphone

(71) Applicant: AAC Acoustic Technologies (Shenzhen) Co., Ltd., Shenzhen (CN)

(72) Inventors: Linlin Wang, Shenzhen (CN); Xiaohui Zhong, Shenzhen (CN); Rui Zhang, Shenzhen (CN); Zhenkui Meng, Shenzhen (CN)

(21) Appl. No.: 16/827,669

(22) Filed: Mar. 23, 2020

(30) Foreign Application Priority Data
Dec. 30, 2019 (CN) 201911402172.0

(51) Int. Cl. H04R 19/04; B81B 3/00; H04R 7/04; H04R 7/18

(52) U.S. Cl. CPC H04R 19/04; B81B 3/0086; H04R 7/04; H04R 2201/003; B81B 2201/0257; B81B 2203/0127; B81B 2203/04; H04R 7/18

(57) ABSTRACT

A MEMS microphone includes a base comprising a back cavity and a capacitive system provided on the base. The capacitive system includes a diaphragm and a back plate spaced from the diaphragm for forming a cavity with the diaphragm. The back plate is provided with an electrode layer. An isolation groove is provided on the back plate for separating the electrode layer into an induction electrode and a floating motor. In the invention the induction electrode is separated from the floating electrode by the isolation groove to avoid the influence of the parasitic capacitance generated by the floating electrode on the MEMS microphone when the MEMS microphone is powered and working.

### FIELD OF THE PRESENT DISCLOSURE

The present invention relates to electroacoustic transducers, and in particular to a MEMS microphone.

### DESCRIPTION OF RELATED ART

A MEMS microphone generally comprises a base and a capacitive system provided on the base. The capacitive system comprises a diaphragm and a back plate that is arranged spaced from the diaphragm and forms a cavity with the diaphragm. The back plate is provided with an electrode layer. The back plate and the diaphragm have charges with opposite polarities when the MEMS microphone is powered and working, at this time, the diaphragm vibrates under the influence of sound waves which causes the distance between the diaphragm and the back plate to change. The distance change leads to the capacitance in the capacitive system to change, so that sound wave is converted into an electric signal, and the corresponding function of the microphone is realized. Because of the existence of a base, as shown in FIG. 1, when the sound wave enters the diaphragm from the cavity, the diaphragm vibrates under the influence of the sound wave, since the diaphragm periphery is not exposed to sound wave so diaphragm periphery does not vibrate, at this time, the distance from the back plate of the diaphragm periphery does not change. But the back plate of this part is also provided with an electrode layer, when the diaphragm vibrates under the influence of sound waves, the electrode layer in the back plate of this part forms parasitic capacitance, which badly affects the value of the capacitance between the diaphragm and the back plate and badly affects the performance of the MEMS microphone.

### SUMMARY OF THE PRESENT INVENTION

One of the major objects of the present invention is to provide an improved MEMS microphone which has lower parasitic capacitance.

To achieve the above-mentioned object, an embodiment of the present invention provides a MEMS microphone including:

a base comprising a back cavity;

a capacitive system provided on the base, the capacitive system having a diaphragm and a back plate spaced from the diaphragm and forming a cavity with the diaphragm;

an electrode layer coupled with the back plate; wherein

an isolation groove is formed in the back plate for separating the electrode layer into an induction electrode located in a middle and a floating electrode surrounding the induction electrode.

Further, the back plate comprises a first insulation layer, an electrode layer, and a second insulation layer which are sequentially stacked, the second insulation layer is disposed opposite to the diaphragm.

Further, a periphery of the first insulation layer is in stair shape and is connected to the base.

Further, the back plate is further provided with a metal layer covering the periphery of the first insulation layer.

Further, the MEMS microphone further comprises a supporting frame disposed between the back plate and the diaphragm, wherein the supporting frame is a hollow circular structure; one end of the supporting frame is connected with the back plate, and the other end is connected with the diaphragm; the supporting frame separates the cavity into a first cavity body located in the middle and a second cavity body located in the periphery.

Further, the supporting frame includes a connection channel, the first cavity body is connected with the second cavity body through the connection channel.

Further, the supporting frame is provided with through holes, the through holes are connection channels connecting the first cavity body and the second cavity body.

Further, the supporting frame comprises multiple supporting cylinders, a gap is set between adjacent supporting cylinders, and the gap is a connection channel connecting the first cavity body and the second cavity body.

Further, a cross section of the supporting cylinder is a square, a circle, a triangle, or a hexagon.

Further, the supporting frame comprises one or multiple supporting cylinder arrays; each supporting cylinder array comprises multiple supporting cylinders, the gap are forms between the adjacent supporting cylinders of each supporting cylinder array; when multiple supporting cylinder arrays are provided, the adjacent supporting cylinder arrays are arranged space from each other along a circle.

### BRIEF DESCRIPTION OF THE DRAWINGS

Many aspects of the exemplary embodiment can be better understood with reference to the following drawings. The components in the drawing are not necessarily drawn to scale, the emphasis instead being placed upon clearly illustrating the principles of the present disclosure.

FIG. 1 is a vertical cross-sectional view of a MEMS microphone related to the present invention.

FIG. 2 is a vertical cross-sectional view of a MEMS microphone in accordance with an exemplary embodiment of the present invention.

FIG. 3 is a vertical cross-sectional view of the MEMS microphone in which a supporting frame is provided.

FIG. 4 is a vertical cross-sectional view of the MEMS microphone in which a plurality of through-holes is provided in the supporting frame in FIG. 3.

### DETAILED DESCRIPTION OF THE EXEMPLARY EMBODIMENT

The present disclosure will hereinafter be described in detail with reference to an exemplary embodiment. To make the technical problems to be solved, technical solutions and beneficial effects of the present disclosure more apparent, the present disclosure is described in further detail together with the figure and the embodiment. It should be understood the specific embodiment described hereby is only to explain the disclosure, not intended to limit the disclosure.

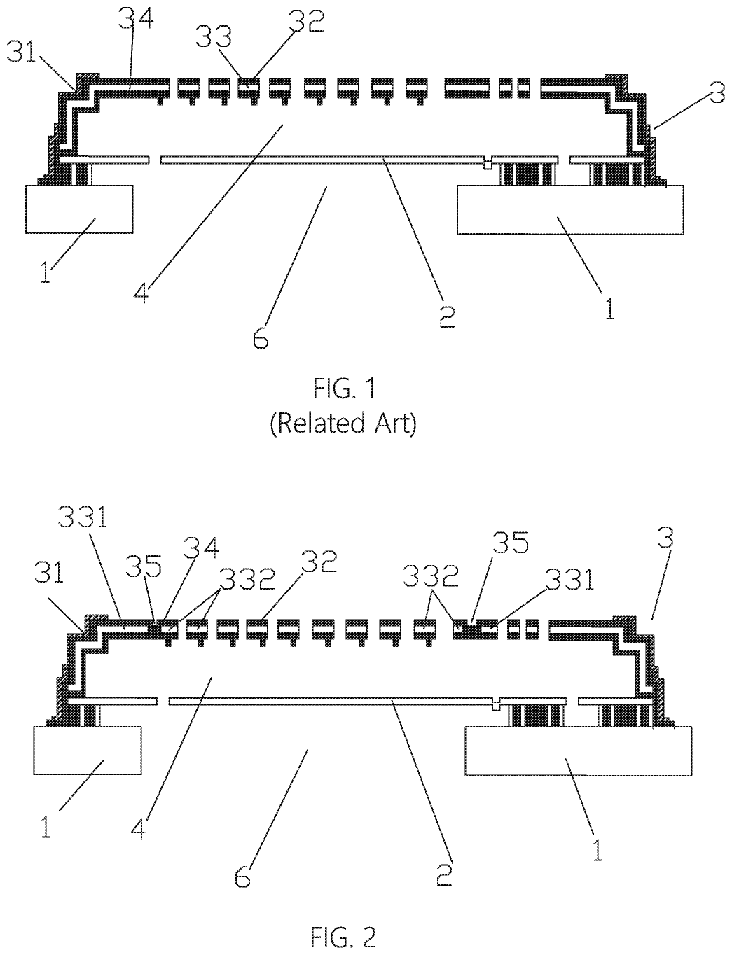

As shown in FIGS. 1-5, an exemplary embodiment of present the invention provides a MEMS microphone which comprises a base 1 comprising a back cavity 6 and a capacitive system provided on the base 1. The capacitive system comprises a diaphragm 2 and a back plate 3 which is arranged spaced from the diaphragm 2 and forms a cavity 4 with the diaphragm 2. The back plate 3 is provided with an electrode layer 33. When the MEMS microphone is powered and working, the diaphragm 2 and back plate 3 respectively have charges of opposite polarity and form a capacitive system. In addition, the back cavity 6 on the base 1 may be formed by a bulk silicon process or dry etching.

When the MEMS microphone is powered and working, the sound wave enters the diaphragm 2 from the back cavity 6 of the base 1 so that the diaphragm 2 vibrates under the influence of the sound wave, by which, the distance between diaphragm 2 and back plate 3 changes, as a result, the capacitance of the capacitive system changes, furthermore, the acoustic signal is converted into electric signal, and the corresponding function of the microphone is realized.

As shown in FIG. 1, when the related MEMS microphone in the current art is powered and working, the electrode layer 33 at the edge portion of the back plate 3 easily generates parasitic capacitance and affects the capacitance change in the capacitive system.

Therefore, as shown in FIG. 2, the present invention provides an embodiment, by arranging isolation groove 35 on the back plate 3. The isolation groove 35 separates the electrode layer 33 into an induction electrode 332 located in the middle and a floating electrode 331 surrounding the induction electrode 332. Wherein, the induction electrode 332 is used to sense a change in capacitance caused by a change in the distance between the diaphragm 2 and the back plate 3.

The isolation groove 35 separates the induction electrode 332 from the floating electrode 331, therefore, when the MEMS microphone is powered and working, the parasitic capacitance generated by the floating electrode 331 does not affect the capacitance change in the capacitive system.

Further, when the MEMS microphone is powered and working, the diaphragm 2 and the back plate 3 respectively have charges of opposite polarities. When the diaphragm 2 is vibrating and when the diaphragm 2 is in contact with the back plate 3, it causes a short circuit which affects the operation of the microphone. Therefore, the back plate 3 in the present invention is further provided with an insulation layer in order to avoid a short circuit. Specifically, the back plate 3 includes a first insulation layer 32, an electrode layer 33, and a second insulation layer 34 which are sequentially stacked. Wherein, the second insulation layer 34 is provided opposite to the diaphragm 2. In this way even though the diaphragm 2 is in contact with the back plate 3 during the vibration, short circuit doesn't occur because the second insulation layer 34 and the diaphragm 2 does not directly contact the electrode layer 33 of back plate 3.

Wherein, the electrode layer 33 is made of poly-silicon, and the first insulation layer 32 and the second insulation layer 34 are both made of silicon nitride.

Preferably, the periphery of the first insulation layer 32 of the back plate 3 shown is in a stair shape and is connected to the base 1.

The periphery of the first insulation layer 32 is further covered with a metal layer 31.

In addition, as shown in FIG. 2, the diaphragm 2 in this embodiment is arranged above the base 1 and with interval from base 1. The diaphragm 2 is arranged under the back plate 3. Similarly, when the back plate 3 is arranged under the diaphragm 2, the isolation groove 35 on the back plate 3 is also applicable.

As shown in FIGS. 1-2, because a certain separation distance between the back plate 3 and the diaphragm 2 exists, when diaphragm 2 vibrates or other external forces exist, it may cause the back plate 3 to dent toward the diaphragm 2 which affects the vibration of diapragm 2.

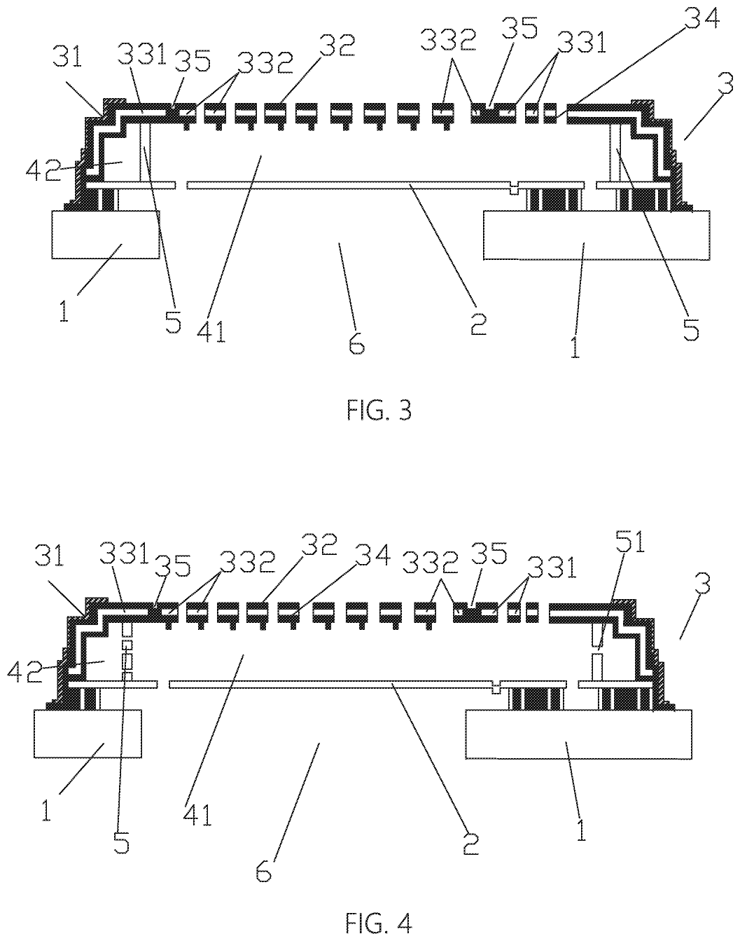

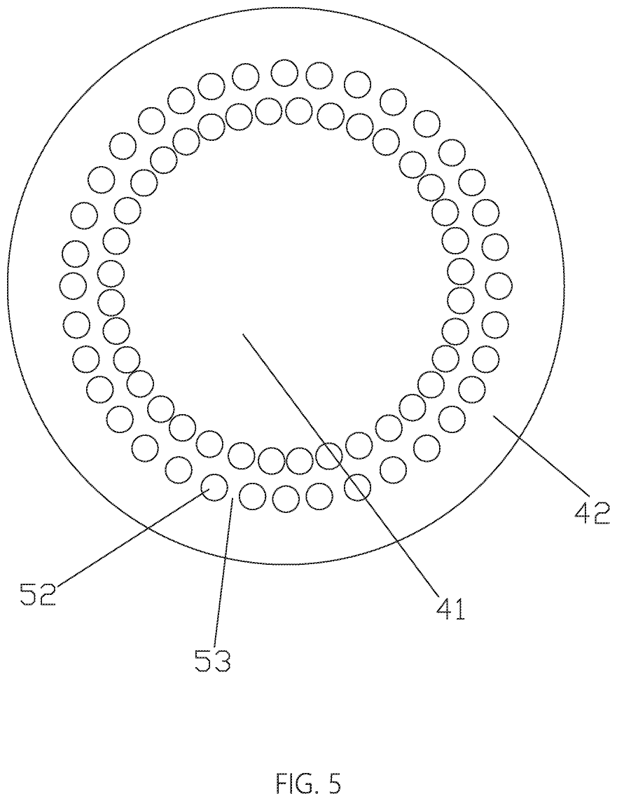

In order to increase the intensity of the back plate 3, as shown in FIGS. 3-4, in the present invention, a supporting frame 5 is provided between the back plate 3 and the diaphragm 2 for supporting the back plate 3 so that the strength of the back plate 3 can be enhanced and the denting of the back plate 3 due to external force or vibration can be prevented.

Further, one end of the supporting frame 5 is connected to the back plate 3 and the other end is connected to the diaphragm 2. The supporting frame 5 separates the cavity 4 into a first cavity body 41 located in the middle and a second cavity body 42 surrounding the first cavity body 41 and located in the periphery. In addition, during the production process of the MEMS microphone, the cavity 4 between back plate 3 and diaphragm 2 is first filled with the corresponding oxide, by letting the etchant enter the cavity 4 between the back plate 3 and the diaphragm 2 from the amplification hole of the back plate 3 to remove the oxide between the back plate 3 and the diaphragm 2. But because the supporting frame 5 separates the cavity 4 into the first cavity body 41 and the second cavity body 42, in the production process the etchant can only enter the first cavity body 41 from the amplification hole of the back plate 3, and the oxide in the second cavity body 42 remains in the product of the MEMS microphone. Due to the existence of the oxide, when the MEMS microphone is powered and working, oxides have an effect on capacitance change in the capacitive system.

Therefore, in order to avoid the residual oxide in the cavity 4, in the present invention a connection channel is arranged on the supporting frame 5, the connection channel enables the first cavity body 41 to connect with the second cavity body 42. In this way in the production process the etchant enters the second cavity body 42 from the first cavity body 41 through the connection channel, and removes the oxide in the second cavity body 42 to prevent the oxide from remaining in the final product.

Further, the supporting frame 5 is a hollow circular structure. The supporting frame 5 can be made of conductive material and can also made of insulating material. Preferably, the supporting frame 5 is provided with a through hole 51, and the through hole 51 is the connection channel connecting the first cavity body 41 and the second cavity body 42. Wherein, multiple through holes 51 are distributed on the supporting frame 5.

Preferably, the supporting frame 5 comprises multiple supporting cylinders 52, a gap 53 is set between adjacent supporting cylinders 52, and the gap 53 is a connection channel connecting the first cavity body 41 and the second cavity body 42.

Further, the cross section of the supporting cylinder 52 is a square, a circle, a triangle or a hexagon.

Further, according to different arrangements of the supporting cylinder 52, the supporting frame 5 further comprises supporting cylinder arrays. Wherein, each supporting cylinder array comprises multiple supporting cylinders 52, and the gap 53 is provided between the adjacent supporting cylinders 52. The gap 53 is also the above-mentioned connection channel connecting the first cavity body 41 and the second cavity body 42.

When multiple supporting cylinder arrays exist, adjacent supporting cylinder arrays are arranged with interval on edge of a circle.

As shown in FIG. 5, in this embodiment, two supporting cylinder arrays are arranged, which are respectively recorded as a first supporting cylinder array and a second supporting cylinder array, the first support array and the second support array are arranged with interval, and the first supporting cylinder array surrounds the second supporting cylinder array. Each supporting cylinder array comprises multiple supporting cylinders 52, and the gap 53 is also provided between the adjacent supporting cylinders 52.

What have been described above are only the embodiments of the present invention. It should be pointed out that, for those of ordinary skill in the art, improvements can be made without departing from the inventive concept of the present invention, but these belong to the present invention. Scope of protection.

It is to be understood, however, that even though numerous characteristics and advantages of the present exemplary embodiment have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A MEMS microphone, including:
a base comprising a back cavity;
s a capacitive system provided on the base, the capacitive system having a diaphragm and a back plate spaced from the diaphragm and forming a cavity with the diaphragm; wherein
an electrode layer is provided in the back plate;
an isolation groove is formed in the back plate for separating the electrode layer into an induction electrode located in a middle and a floating electrode surrounding the induction electrode.

2. The MEMS microphone as described in claim 1, wherein the back plate comprises a first insulation layer and a second insulation layer, the first insulation layer, the electrode layer, and the second insulation layer are sequentially stacked, the second insulation layer is disposed opposite to the diaphragm.

3. The MEMS microphone as described in claim 2, wherein a periphery of the first insulation layer is in stair shape and is connected to the base .

4. The MEMS microphone as described in claim 3, wherein the back plate is further provided with a metal layer covering the periphery of the first insulation layer.

5. The MEMS microphone as described in claim 1 further comprising a supporting frame disposed between the back plate and the diaphragm, wherein the supporting frame is a hollow circular structure; one end of the supporting frame is connected with the back plate, and the other end is connected with the diaphragm; the supporting frame separates the cavity into a first cavity body located in the middle and a second cavity body located in the periphery.

6. The MEMS microphone as described in claim 5, wherein the supporting frame includes a connection channel, the first cavity body is connected with the second cavity body through the connection channel.

7. The MEMS microphone as described in claim 6, wherein the supporting frame is provided with through holes, the through holes are connection channels connecting the first cavity body and the second cavity body.

8. The MEMS microphone as described in claim 6, wherein the supporting frame comprises multiple supporting cylinders, a gap is set between adjacent supporting cylinders, and the gap is a connection channel connecting the first cavity body and the second cavity body.

9. The MEMS microphone as described in claim 8, wherein a cross section of the supporting cylinder is a square, a circle, a triangle, or a hexagon.

10. The MEMS microphone as described in claim 8, wherein the supporting frame comprises one or multiple supporting cylinder arrays; each supporting cylinder array comprises multiple supporting cylinders, the gap are forms between the adjacent supporting cylinders of each supporting cylinder array; when multiple supporting cylinder arrays are provided, the adjacent supporting cylinder arrays are arranged space from each other along a circle.
